(19) United States
(12) Patent Application Publication
(10) Pub. No.: US 2025/0354255 A1
(43) Pub. Date: Nov. 20, 2025

(54) MASK AND DEPOSITION APPARATUS INCLUDING SAME

(71) Applicant: Samsung Display Co., LTD., Yongin-si (KR)

(72) Inventor: Duck Jung LEE, Yongin-si (KR)

(73) Assignee: Samsung Display Co., LTD., Yongin-si (KR)

(21) Appl. No.: 19/012,189

(22) Filed: Jan. 7, 2025

(30) Foreign Application Priority Data
May 14, 2024 (KR) 10-2024-0063176

(51) Int. Cl. C23C 16/04; H10K 59/122

(52) U.S. Cl. CPC C23C 16/042; H10K 59/122

(57) ABSTRACT

A deposition mask includes a substrate with a cell pattern disposed in each of a plurality of cell openings in the substrate. The cell pattern is formed by an inorganic film and includes a mask membrane pattern with a plurality of openings. A dummy pattern surrounds the mask membrane pattern, and the width of the dummy pattern is irregular. A deposition apparatus includes the deposition mask.

### CROSS-REFERENCE TO RELATED APPLICATION(S)

This application claims priority to and benefits of Korean Patent Application No. 10-2024-0063176 under 35 U.S.C. § 119, filed on May 14, 2024 in the Korean Intellectual Property Office (KIPO), the entire contents of which are incorporated herein by reference.

### BACKGROUND

### 1. Technical Field

Embodiments relate to a mask and a deposition apparatus (or deposition equipment) including the mask.

### 2. Description of the Related Art

Wearable devices which form a focus at a distance close to user's eyes have been developed in the form of glasses or helmets. For example, the wearable device may include a head mounted display (HMD) device or an augmented reality (AR) glass. The wearable device provides an AR screen or a virtual reality (VR) screen to a user.

Wearable devices such as HMD devices or AR glasses require a display specification of at least 2000 PPI (pixels per inch) so that a user may use it for a long time without causing dizziness. To this end, organic light-emitting diode on silicon (OLEDoS) technology, a high-resolution small organic light-emitting display device, is emerging. OLEDOS involves disposing an organic light-emitting diode (OLED) on a semiconductor wafer substrate, on which a complementary metal oxide semiconductor (CMOS) is located.

### SUMMARY

Embodiments provide a mask that functions as a deposition mask for manufacturing a high-resolution organic light emitting display device, where reliability is improved by increasing pixel position accuracy (PPA) reliability, and deposition equipment (or apparatus) that includes the mask.

Embodiments also provide a mask that may reduce shadow defects and the accumulation of deposition material on the mask, as well as deposition equipment (or apparatus) that includes the mask.

However, embodiments are not limited to those described herein. The above and other embodiments will be apparent to those of ordinary skill in the art by referencing the detailed description provided below.

According to an embodiment, a deposition mask may include a substrate, and a cell pattern disposed in each of multiple cell openings in the substrate, formed by an inorganic film. The cell pattern may include a mask membrane pattern comprising multiple openings, and a dummy pattern surrounding the mask membrane pattern, where the width of the dummy pattern is irregular.

In an embodiment, the multiple cell openings may include at least one first type cell opening adjacent to the center portion of the substrate, comprising a first cell pattern, and multiple second type cell openings disposed at the periphery of the first type cell opening, comprising a second cell pattern. The width of a dummy pattern included in the first cell pattern may be uniform, and the width of a dummy pattern included in the second cell pattern may be irregular.

In an embodiment, the first cell pattern may include a first dummy pattern disposed on a side of the mask membrane pattern and having a first width, and a second dummy pattern disposed on another side of the mask membrane pattern and having the first width.

In an embodiment, the second cell pattern may include a first dummy pattern disposed on a side of the mask membrane pattern and having a first width, and a second dummy pattern disposed on another side of the mask membrane pattern and having a second width greater than the first width. The second dummy pattern may be closer to the center portion of the substrate than the first dummy pattern.

In an embodiment, the multiple second type cell openings may include a first cell opening including a first dummy pattern and a second dummy pattern, spaced apart from the center portion of the substrate by a first distance, and a second cell opening including a third dummy pattern and a fourth dummy pattern, spaced apart from the center portion of the substrate by a second distance smaller than the first distance. The width of each of the first to fourth dummy patterns may be different from one another.

In an embodiment, the first dummy pattern may have a first width, the second dummy pattern may have a second width greater than the first width, the third dummy pattern may have a third width, and the fourth dummy pattern may have a fourth width greater than the third width.

In an embodiment, the first width may be different from the third width, and the second width may be different from the fourth width.

In an embodiment, the inorganic film may include a first inorganic film containing silicon oxide (SiOₓ), and a second inorganic film disposed on the first inorganic film, containing silicon nitride (SiNₓ).

In an embodiment, the inorganic film may contain at least one of silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

In an embodiment, the substrate may contain silicon (Si).

According to an embodiment, deposition equipment (or apparatus) may include a deposition source, and a mask disposed between a first substrate and the deposition source. The mask may include a second substrate and a cell pattern disposed in each of multiple cell openings of the second substrate formed by an inorganic film. The cell pattern may include a mask membrane pattern comprising multiple openings and a dummy pattern surrounding the mask membrane pattern, where a width of the dummy pattern is irregular.

In an embodiment, the multiple cell openings may include at least one first type cell opening adjacent to the center portion of the second substrate, comprising a first cell pattern, and multiple second type cell openings disposed at the periphery of the first type cell opening, comprising a second cell pattern. The width of a dummy pattern included in the first cell pattern may be uniform, and the width of a dummy pattern included in the second cell pattern may be irregular.

In an embodiment, the first cell pattern may include a first dummy pattern disposed on a side of the mask membrane pattern, having a first width, and a second dummy pattern disposed on another side of the mask membrane pattern, also having the first width.

In an embodiment, the second cell pattern may include a first dummy pattern disposed on a side of the mask membrane pattern, having a first width, and a second dummy pattern disposed on another side of the mask membrane pattern, having a second width greater than the first width. The second dummy pattern may be closer to the center portion of the second substrate than the first dummy pattern.

In an embodiment, the multiple second type cell openings may include a first cell opening comprising a first dummy pattern and a second dummy pattern, spaced apart from the center portion of the second substrate by a first distance, and a second cell opening comprising a third dummy pattern and a fourth dummy pattern, spaced apart from the center portion of the second substrate by a second distance smaller than the first distance. The width of each of the first to fourth dummy patterns may be different from one another.

In an embodiment, the first dummy pattern may have a first width, the second dummy pattern may have a second width greater than the first width, the third dummy pattern may have a third width, and the fourth dummy pattern may have a fourth width greater than the third width.

In an embodiment, the first width may be different from the third width, and the second width may be different from the fourth width.

In an embodiment, the inorganic film may include a first inorganic film containing silicon oxide (SiOₓ), and a second inorganic film disposed on the first inorganic film, containing silicon nitride (SiNₓ).

In an embodiment, the inorganic film may contain at least one of silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

In an embodiment, the second substrate may contain silicon (Si).

According to an embodiment, reliability may be improved by enhancing pixel position accuracy (PPA).

According to an embodiment, shadow defects and accumulation of deposition material on the mask may also be reduced.

### BRIEF DESCRIPTION OF THE DRAWINGS

The above and other aspects, features, and advantages of embodiments will be more apparent from the following description taken in conjunction with the accompanying drawings, in which:

FIG. 1 is an exploded schematic perspective view showing a display device according to an embodiment;

FIG. 2 is a schematic block diagram illustrating a display device according to an embodiment;

FIG. 3 is a schematic equivalent circuit diagram of a first sub-pixel according to an embodiment;

FIG. 4 is a schematic layout diagram illustrating an example of a display panel according to an embodiment;

FIGS. 5 and 6 are schematic layout diagrams illustrating embodiments of the display area of FIG. 4;

FIG. 7 is a schematic cross-sectional view illustrating an example of a display panel taken along line I1-I1′ of FIG. 5;

FIG. 8 is a schematic perspective view illustrating a head mounted display according to an embodiment;

FIG. 9 is an exploded schematic perspective view illustrating an example of the head mounted display of FIG. 8;

FIG. 10 is a schematic perspective view illustrating a head mounted display according to an embodiment;

FIG. 11 is a schematic perspective view of a mask according to an embodiment;

FIG. 12 is a schematic plan view of a mask according to an embodiment;

FIGS. 13 to 15 are schematic process cross-sectional views illustrating a method of manufacturing a mask according to an embodiment;

FIG. 16 is a schematic diagram explaining a shadow defect that occurs during a deposition process using a mask;

FIGS. 17 to 18 are schematic configuration diagrams of a mask according to a comparative example;

FIGS. 19 to 20 are schematic configuration diagrams of a mask according to an embodiment; and

FIG. 21 is a schematic configuration diagram illustrating deposition equipment (or apparatus) according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment. In the drawings, sizes, thicknesses, ratios, and dimensions of elements may be exaggerated for ease of description and for clarity. Like reference numbers and/or reference characters refer to like elements throughout.

Some of the parts which are not relevant to the description may be omitted to describe embodiments of the disclosure.

As used herein, the singular forms “a,” “an,” and “the” are intended to include the plural forms as well, unless the context clearly indicates otherwise.

In the case where an element, such as a layer, a region, a portion, or the like, is referred to as being “on,” “connected to,” or “coupled to” another element or layer, it may be directly on, connected to, or coupled to another element or layer, or intervening elements or layers may also be present. In contrast, in the case where an element or layer is referred to as being “directly on,” “directly connected to,” or “directly coupled to” another element or layer, there may be no intervening elements or layers present. The term “connected” or “coupled” may refer to physical, electrical, and/or fluid connections, including cases where an element is “electrically connected” or “electrically coupled,” with or without intervening elements.

The phrase “in a plan view” means viewing an object from the top, and the phrase “in a schematic cross-sectional view” means viewing a schematic cross-section of which an object is vertically cut from the side. Hence, the phrase “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

The terms “overlap” or “overlapped” refer to a first object being positioned above, below, to a side of, or in any other positional relationship with a second object. The term “overlap” may also include configurations such as layering, stacking, facing, extending over, covering, or partially covering, as well as any other suitable relationships that would be understood by those of ordinary skill in the art. The term “not overlap” may refer to configurations where objects are “apart from,” “set aside from,” “offset from,” or in other equivalent spatial arrangements, as would be appreciated by those skilled in the art. The terms “face” and “facing” refer to a first object directly or indirectly opposing a second object. In a case where a third object is positioned between the first and second objects, the first and second objects may still be considered to face each other indirectly.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “comprises,” “comprising,” “includes,” “including,” “has,” “have,” and/or “having,” and variations thereof when used in this specification, may specify the presence of stated features, integers, steps, operations, elements, components, and/or groups thereof, but do not preclude the presence or addition of one or more other features, integers, steps, operations, elements, components, and/or groups thereof.

It will be understood that, although the terms “first,” “second,” “third,” or the like may be used herein to describe various elements, these elements should not be limited by these terms. These terms are used to distinguish one element from another or for convenience in description and explanation. For example, a “first element” may be referred to as a “second element” or a “third element,” and similarly, a “second element” or a “third element” may be referred to as a “first element” or a “second element” without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, 20%, 10%, 5% of the stated value.

The term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

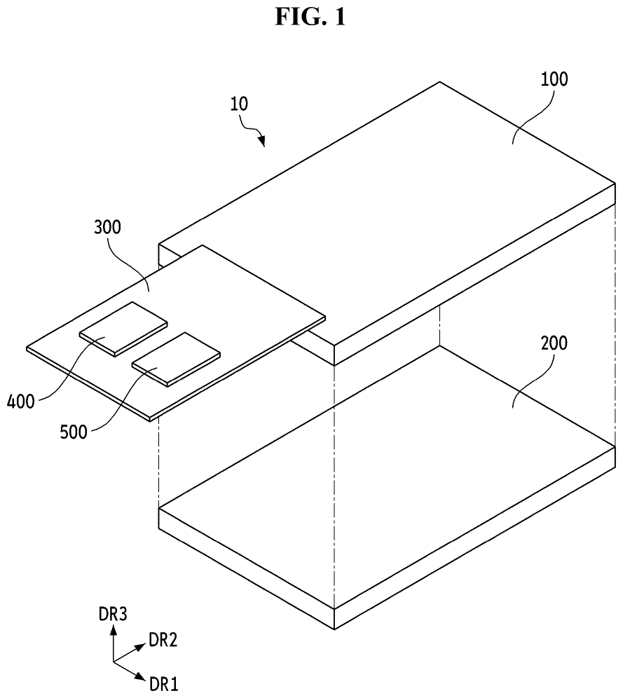

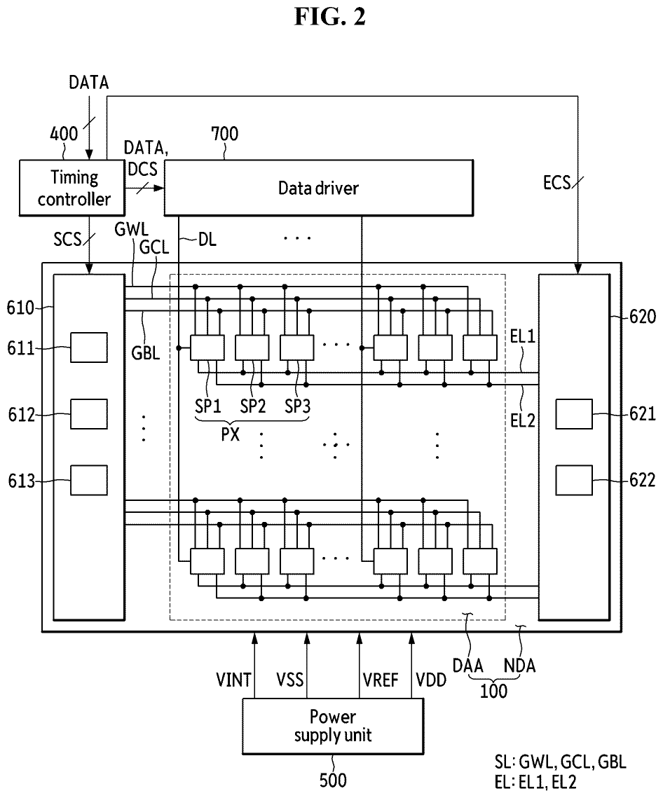

FIG. 1 is an exploded schematic perspective view showing a display device according to an embodiment. FIG. 2 is a schematic block diagram illustrating a display device according to an embodiment.

Referring to FIGS. 1 and 2, a display device 10 according to an embodiment may be a device for displaying a moving image or a still image. The display device 10 according to an embodiment may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC), or the like. For example, the display device 10 according to an embodiment may be applied as a display unit for a television, a laptop, a monitor, a billboard, or an Internet-of-Things (IoT) terminal. In another embodiment, the display device 10 according to an embodiment may be applied to a smart watch, a watch phone, a head mounted display (HMD) for implementing virtual reality and augmented reality, and the like.

The display device 10 according to an embodiment may include a display panel 100, a heat dissipation layer 200, a circuit board 300, a timing controller 400, and a power supply circuit 500.

The display panel 100 may have a planar shape similar to a quadrilateral shape. For example, the display panel 100 may have a planar shape similar to a quadrilateral shape, having a short side in a first direction DR1 and a long side in a second direction DR2, which intersects the first direction DR1. In the display panel 100, a corner where the short side in the first direction DR1 and the long side in the second direction DR2 meet may be right-angled or rounded with a selected curvature. The planar shape of the display panel 100 is not limited to a quadrilateral shape and may be a shape similar to another polygonal shape, a circular shape, or an elliptical shape. The planar shape of the display device 10 may conform to the planar shape of the display panel 100, but this disclosure is not limited thereto.

The display panel 100 may include a display area DAA for displaying an image and a non-display area NDA that does not display an image, as shown in FIG. 2.

The display area DAA may include multiple pixels PX, multiple scan lines SL, multiple emission control lines EL, and multiple data lines DL.

The multiple pixels PX may be arranged in a matrix form in the first direction DR1 and the second direction DR2. The scan lines SL and the emission control lines EL may extend in the first direction DR1, while being arranged in the second direction DR2. The data lines DL may extend in the second direction DR2, while being arranged in the first direction DR1.

The multiple scan lines SL may include write scan lines GWL, control scan lines GCL, and bias scan lines GBL. The emission control lines EL may include first emission control lines EL1 and second emission control lines EL2.

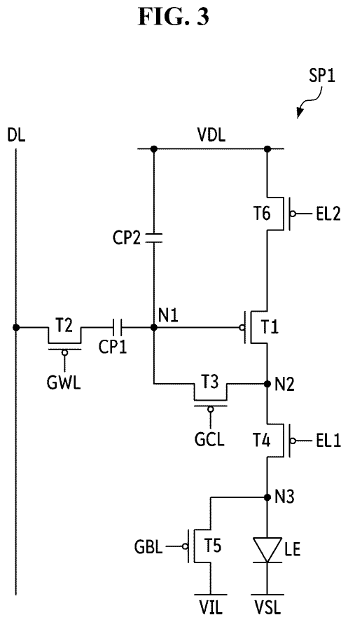

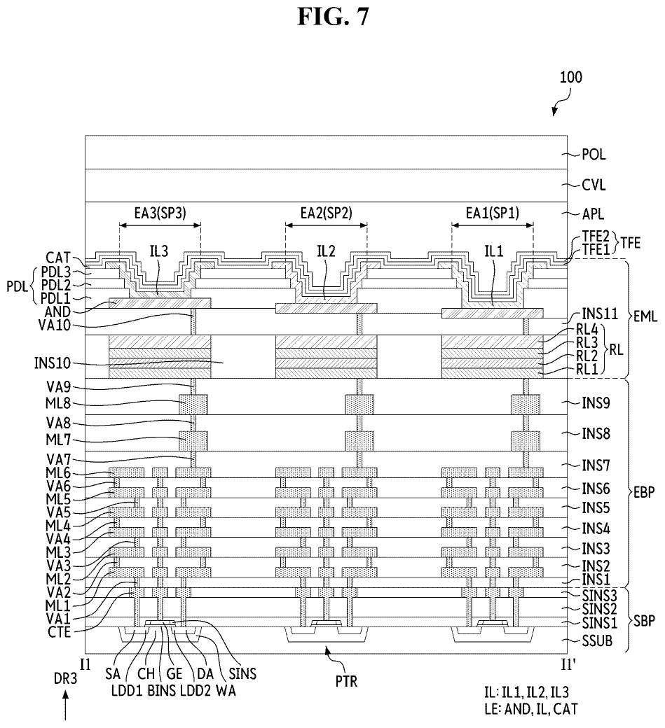

The multiple pixels PX may include sub-pixels SP1, SP2, and SP3. The sub-pixels SP1, SP2, and SP3 may include multiple pixel transistors as shown in FIG. 3, and these pixel transistors may be formed by a semiconductor process and disposed on a semiconductor substrate SSUB (see FIG. 7). For example, the pixel transistors of a data driver 700 may be formed of complementary metal oxide semiconductor (CMOS).

Each of the sub-pixels SP1, SP2, and SP3 may be connected to any one of the write scan lines GWL, any one of the control scan lines GCL, any one of the bias scan lines GBL, any one of the first emission control lines EL1, any one of the second emission control lines EL2, and any one of the data lines DL. Each of the sub-pixels SP1, SP2, and SP3 may receive a data voltage of the data line DL in response to a write scan signal of the write scan line GWL, and emit light from the light-emitting element according to the data voltage.

The non-display area NDA may include a scan driver 610, an emission driver 620, and a data driver 700.

The scan driver 610 may include multiple scan transistors, and the emission driver 620 may include multiple light-emitting transistors. The scan transistors and the light-emitting transistors may be formed on the semiconductor substrate SSUB (see FIG. 7) through a semiconductor process. For example, the scan transistors and light-emitting transistors may be formed of CMOS. Although FIG. 2 illustrates the scan driver 610 on the left side of the display area DAA and the emission driver 620 on the right side of the display area DAA, this disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals based on the scan timing control signal SCS from the timing controller 400 and output them sequentially to the write scan lines GWL. The control scan signal output unit 612 may generate control scan signals in response to the scan timing control signal SCS and output them sequentially to the control scan lines GCL. The bias scan signal output unit 613 may generate bias scan signals based on the scan timing control signal SCS and output them sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing controller 400. The first emission control driver 621 may generate first emission control signals based on the emission timing control signal ECS and output them sequentially to the first emission control lines EL1. The second emission control driver 622 may generate second emission control signals based on the emission timing control signal ECS and output them sequentially to the second emission control lines EL2.

The data driver 700 may include multiple data transistors, which may be formed on the semiconductor substrate SSUB (see FIG. 7) through a semiconductor process. For example, the data transistors may be formed of CMOS.

The data driver 700 may receive digital video data DATA and a data timing control signal DCS from the timing controller 400. The data driver 700 may convert the digital video data DATA into analog data voltages according to the data timing control signal DCS and outputs the analog data voltages to the data lines DL. The sub-pixels SP1, SP2, and SP3 may be selected by the write scan signal from the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on a surface of the display panel 100, for example, on its rear surface. The heat dissipation layer 200 may serve to dissipate heat generated by the display panel 100. The heat dissipation layer 200 may include a metal layer, such as graphite, silver (Ag), copper (Cu), or aluminum (Al) having high thermal conductivity.

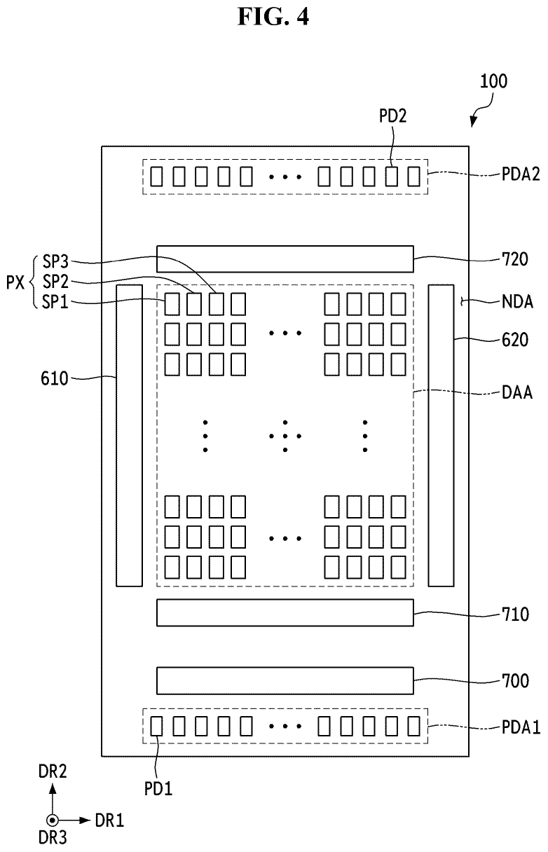

The circuit board 300 may be electrically connected to multiple first pads PD1 (see FIG. 4) of a first pad portion PDA1 (see FIG. 4) of the display panel 100 using a conductive adhesive member, such as an anisotropic conductive film. The circuit board 300 may be a flexible printed circuit board made of a flexible material or a flexible film. Although the circuit board 300 is illustrated as being unfolded in FIG. 1, the circuit board 300 may be bent. An end of the circuit board 300 may be disposed on the rear surface of the display panel 100 and/or the rear surface of the heat dissipation layer 200. An end of the circuit board 300 may be opposite to the end connected to the first pads PD1 (see FIG. 4) of the first pad portion PDA1 (see FIG. 4) of the display panel 100 using a conductive adhesive member.

The timing controller 400 may receive digital video data DATA and timing signals from external sources. The timing controller 400 may generate the scan timing control signal SCS, the emission timing control signal ECS, and the data timing control signal DCS to control the display panel 100 in response to the timing signals. The timing controller 400 may output the scan timing control signal SCS to the scan driver 610, and output the emission timing control signal ECS to the emission driver 620. The timing controller 400 may output the digital video data DATA and the data timing control signal DCS to the data driver 700.

The power supply circuit 500 may generate multiple panel driving voltages according to an external power voltage. For example, the power supply circuit 500 may generate a first driving voltage VSS, a second driving voltage VDD, and a third driving voltage VINT, and supply them to the display panel 100. The first driving voltage VSS, the second driving voltage VDD, and the third driving voltage VINT will be described later in conjunction with FIG. 3.

Each of the timing controller 400 and the power supply circuit 500 may be formed as an integrated circuit (IC) and attached to a surface of the circuit board 300. The scan timing control signal SCS, the emission timing control signal ECS, the digital video data DATA, and the data timing control signal DCS from the timing controller 400 may be supplied to the display panel 100 through the circuit board 300. The first driving voltage VSS, the second driving voltage VDD, and the third driving voltage VINT from the power supply circuit 500 may be supplied to the display panel 100 through the circuit board 300.

In another embodiment, similarly to the scan driver 610, the emission driver 620, and the data driver 700, each of the timing controller 400 and the power supply circuit 500 may be disposed in the non-display area NDA of the display panel 100. The timing controller 400 may include multiple timing transistors, and the power supply circuit 500 may include multiple power transistors. The timing transistors and the power transistors may be formed on the semiconductor substrate SSUB (see FIG. 7) through a semiconductor process. For example, the timing transistors and the power transistors may be formed of CMOS. Each of the timing controller 400 and the power supply circuit 500 may be disposed between the data driver 700 and the first pad portion PDA1 (see FIG. 4).

FIG. 3 is a schematic equivalent circuit diagram of a first sub-pixel according to an embodiment.

Referring to FIG. 3, the first sub-pixel SP1 may be connected to the write scan line GWL, the control scan line GCL, the bias scan line GBL, the first emission control line EL1, the second emission control line EL2, and the data line DL. The first sub-pixel SP1 may be connected to a first driving voltage line VSL, where the first driving voltage VSS corresponding to a low potential voltage is applied, a second driving voltage line VDL, where the second driving voltage VDD corresponding to a high potential voltage is applied, and a third driving voltage line VIL, where the third driving voltage VINT corresponding to an initialization voltage is applied. The first driving voltage line VSL may be a low potential voltage line, the second driving voltage line VDL may be a high potential voltage line, and the third driving voltage line VIL may be an initialization voltage line. The first driving voltage VSS may be lower than the third driving voltage VINT. The second driving voltage VDD may be higher than the third driving voltage VINT.

The first sub-pixel SP1 may include multiple transistors T1 to T6, a light-emitting element LE, a first capacitor CP1, and a second capacitor CP2.

The light-emitting element LE may emit light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode, including a first electrode, a second electrode, and an organic light-emitting layer disposed between the first electrode and the second electrode, but this disclosure is not limited thereto. For example, the light-emitting element LE may be an inorganic light-emitting element, such as a micro light-emitting diode, that includes a first electrode, a second electrode, and an inorganic semiconductor disposed between the first electrode and the second electrode.

The first transistor T1 may be a driving transistor that controls a drain-source current (hereinafter referred to as “driving current”) flowing between its source electrode and drain electrode according to a voltage applied to its gate electrode. The first transistor T1 may include a gate electrode connected to a first node N1, a source electrode connected to the drain electrode of a sixth transistor T6, and a drain electrode connected to a second node N2.

A second transistor T2 may be disposed between an electrode of the first capacitor CP1 and the data line DL. The second transistor T2 may be turned on by the write scan signal of the write scan line GWL, connecting the electrode of the first capacitor CP1 to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by the write control signal of the control scan line GCL, connecting the first node N1 to the second node N2. For this reason, since the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal from the first emission control line EL1, connecting the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal from the bias scan line GBL, connecting the third node N3 to the third driving voltage line VIL. Accordingly, the third driving voltage VINT from the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal from the second emission control line EL2, connecting the source electrode of the first transistor T1 to the second driving voltage line VDL. Accordingly, the second driving voltage VDD from the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed between the first node N1 and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a junction between the gate electrode of the first transistor T1, the drain electrode of the third transistor T3, the electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the disclosure is not limited thereto. Each of the first to sixth transistors T1 to T6 may be an N-type MOSFET. In another embodiment, some of the first to sixth transistors T1 to T6 may be P-type MOSFETs, and the remaining transistors may be N-type MOSFETs.

Although FIG. 3 illustrates that the first sub-pixel SP1 includes six transistors T1 to T6 and two capacitors C1 and C2, the equivalent circuit diagram of the first sub-pixel SP1 is not limited to that shown in FIG. 3. For example, the number of transistors and capacitors in the first sub-pixel SP1 is not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagrams of the second sub-pixel SP2 and the third sub-pixel SP3 is not repeated in this disclosure.

FIG. 4 is a schematic layout diagram illustrating an example of a display panel according to an embodiment.

Referring to FIG. 4, the display area DAA of the display panel 100 according to an embodiment includes multiple pixels PX arranged in a matrix form. The non-display area NDA of the display panel 100 according to an embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. The scan driver 610 may be disposed on the left side of the display area DAA, and the emission driver 620 may be disposed on the right side of the display area DAA. However, this disclosure is not limited thereto, and the scan driver 610 and the emission driver 620 may be disposed on both the first side and the second side of the display area DAA.

The first pad portion PDA1 may include multiple first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include multiple second pads PD2, which function as inspection pads to test whether the display panel 100 operates normally. The second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 may distribute data voltages applied through the first pad portion PDA1 to multiple data lines DL. For example, the first distribution circuit 710 may distribute the data voltages applied through one first pad PD1 of the first pad portion PDA1 to P (P is a positive integer of 2 or more) data lines DL, reducing the number of the first pads PD1. The first distribution circuit 710 may be disposed on the third side of the display area DAA of the display panel 100. For example, the first distribution circuit 710 may be disposed on one side of the display area DAA in the second direction DR2. For example, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA.

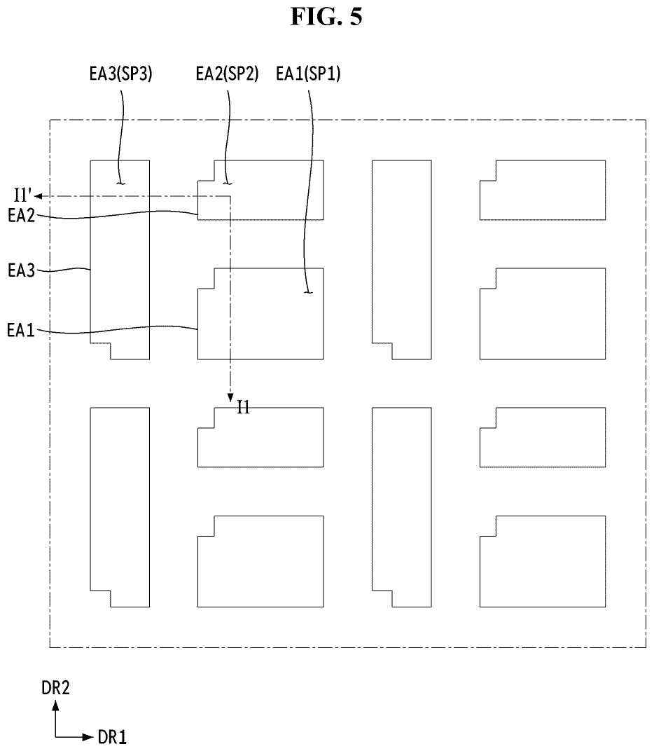

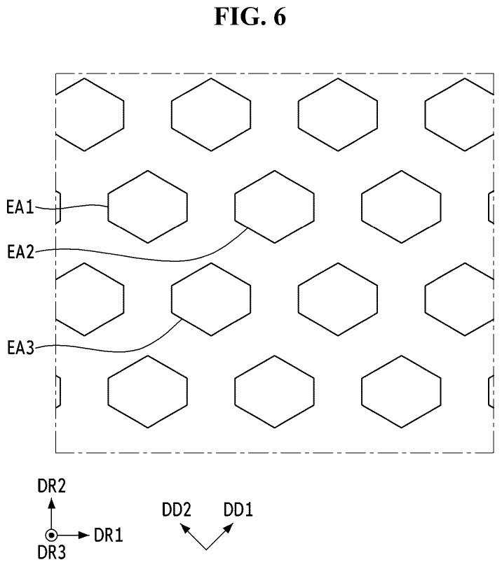

FIGS. 5 and 6 are schematic layout diagrams illustrating embodiments of the display area of FIG. 4.

Referring to FIGS. 5 and 6, each of the pixels PX includes the first emission area EA1, that is an emission area of the first sub-pixel SP1, the second emission area EA2, that is an emission area of the second sub-pixel SP2, and the third emission area EA3, that is an emission area of the third sub-pixel SP3.

Each of the first emission area EA1, the second emission area EA2, and the third emission area EA3 may have a polygonal, circular, elliptical, or atypical shape in a plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIGS. 5 and 6, but the disclosure is not limited thereto. The first emission area EA1, the second emission area EA2, and the third emission area EA3 may have a polygonal shape other than a hexagon, a circular shape, an elliptical shape, or an atypical shape in a plan view.

As shown in FIG. 5, in each of the multiple pixels PX, the first emission area EA1 and the second emission area EA2 may be adjacent to each other in the second direction DR2. The first emission area EA1 and the third emission area EA3 may be adjacent to each other in the first direction DR1. The second emission area EA2 and the third emission area EA3 may be adjacent to each other in the first direction. The area of the first emission area EA1, the area of the second emission area EA2, and the area of the third emission area EA3 may be different.

In another embodiment, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2. The second diagonal direction DD2 may be perpendicular to the first diagonal direction DD1.

The first emission area EA1 may emit first light, the second emission area EA2 may emit second light, and the third emission area EA3 may emit third light. The first light may be light in a blue wavelength band, the second light may be light in a green wavelength band, and the third light may be light in a red wavelength band. For example, the blue wavelength band may have a main peak wavelength in the range of about 370 nm to about 460 nm, the green wavelength band may have a main peak wavelength in the range of about 480 nm to about 560 nm, and the red wavelength band may have a main peak wavelength in the range of about 600 nm to about 750 nm.

Although FIGS. 5 and 6 depict that each of the multiple pixels PX includes three emission areas EA1, EA2, and EA3, the disclosure is not limited thereto. For example, each of the multiple pixels PX may include four emission areas.

The layout of the emission areas in the pixels PX is not limited to those illustrated in FIGS. 5 and 6. For example, the emission areas in the pixels PX may be disposed in a stripe structure where the emission areas are arranged in the first direction DR1, a PenTile® structure where the emission areas are arranged in a diamond shape, or a hexagonal structure where the emission areas, having a hexagonal shape in a plan view, are arranged as shown in FIG. 6.

FIG. 7 is a schematic cross-sectional view illustrating an example of a display panel taken along line I1-I1′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP may include a semiconductor substrate SSUB including multiple pixel transistors PTR, multiple semiconductor insulating films covering the pixel transistors PTR, and multiple contact terminals CTE electrically connected to the pixel transistors PTR, respectively. The pixel transistors PTR may correspond to the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. Multiple well regions WA may be disposed on the top surface of the semiconductor substrate SSUB. These well regions WA may be doped with a second type impurity, which is different from the first type. For example, in the case where the first type impurity is a p-type impurity, the second type impurity may be an n-type impurity. In another embodiment, in the case where the first type impurity is an n-type impurity, the second type impurity may be a p-type impurity.

Each of the well regions WA may include a source region SA corresponding to the source electrode of the pixel transistor PTR, a drain region DA corresponding to the drain electrode, and a channel region CH disposed between the source region SA and the drain region DA.

A lower insulating film BINS may be disposed between a gate electrode GE and the well region WA. A side insulating film SINS may be disposed on the side surface of the gate electrode GE, also covering the lower insulating film BINS.

Each of the source region SA and the drain region DA may be doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of the multiple well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may have a lower impurity concentration than the source region SA due to the lower insulating film BINS. The second low-concentration impurity region LDD2 may have a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH in each of the pixel transistors PTR may increase, so that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the disclosure is not limited thereto.

Multiple contact terminals CTE may be disposed on the second semiconductor insulating film SINS2. Each of the contact terminals CTE may be connected to any one of the gate electrode GE, the source region SA, and the drain region DA of each of the pixel transistors PTR through a hole penetrating both the first semiconductor insulating film SINS1 and the second semiconductor insulating film INS2. The contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the contact terminals CTE. The top surface of each of the contact terminals CTE may be exposed, without being covered by the third semiconductor insulating film SINS3. The third semiconductor insulating film SINS3 may be formed of a silicon oxide (SiOₓ)-based inorganic film, but the disclosure is not limited thereto.

The semiconductor substrate SSUB may be replaced with a glass substrate or a polymer resin substrate such as polyimide. Thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include multiple conductive layers ML1 to ML8, multiple vias VA1 to VA9, and multiple insulating films INS1 to INS9. The light-emitting element backplane EBP may include multiple insulating films INS1 to INS9 disposed between the semiconductor backplane SBP and the display element layer EML.

The first to eighth conductive layers ML1 to ML8 may serve to connect the contact terminals CTE exposed from the semiconductor backplane SBP, thereby implementing the circuit of the first sub-pixel SP1 shown in FIG. 3. For example, while the first to sixth transistors T1 to T6 are merely formed in the semiconductor backplane SBP, the connection of the first to sixth transistors T1 to T6, as well as the connection of the first and second capacitors C1 and C2, are accomplished through the first to eighth conductive layers ML1 to ML8. The connection between the drain region corresponding to the drain electrode of the fourth transistor T4, the source region corresponding to the source electrode of the fifth transistor T5, and the first electrode of the light-emitting element LE may also be accomplished through the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. The first to eighth vias VA1 to VA8 may be made of substantially the same material. First to eighth insulating films INS1 to INS8 may be formed of a silicon oxide (SiOₓ)-based inorganic film, but the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but the disclosure is not limited thereto.

Each of the ninth vias VA9 may penetrate the ninth insulating film INS9 and be connected to the exposed eighth conductive layer ML8. The ninth vias VA9 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. The thickness of the ninth via VA9 may be approximately 16500 Å.

The display element layer EML may be disposed on the light-emitting element backplane EBP. The display element layer EML may include light-emitting elements LE, each including a reflective electrode layer RL, tenth and eleventh insulating films INS10 and INS11, a tenth via VA10, the first electrode AND, a light-emitting stack IL, and a second electrode CAT; and a pixel defining film PDL.

The reflective electrode layer RL may be disposed on the ninth insulating film INS9. The reflective electrode layer RL may include at least one reflective electrode, such as RL1, RL2, RL3, and RL4. For example, the reflective electrode layer RL may include first to fourth reflective electrodes RL1, RL2, RL3, and RL4, as shown in FIG. 7.

Each of the first reflective electrodes RL1 may be disposed on the ninth insulating film INS9, and may be connected to the ninth via VA9. The first reflective electrodes RL1 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. For example, the first reflective electrodes RL1 may include titanium nitride (TiN).

Each of the second reflective electrodes RL2 may be disposed on the first reflective electrode RL1. The second reflective electrodes RL2 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. For example, the second reflective electrodes RL2 may include aluminum (Al).

Each of the third reflective electrodes RL3 may be disposed on the second reflective electrode RL2. The third reflective electrodes RL3 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. For example, the third reflective electrodes RL3 may include titanium nitride (TiN).

Each of the fourth reflective electrodes RL4 may be disposed on the third reflective electrode RL3. The fourth reflective electrodes RL4 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. For example, the fourth reflective electrodes RL4 may include titanium (Ti).

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL that are adjacent to each other in a horizontal direction. The tenth insulating film INS10 may be formed of a silicon oxide (SiOₓ)-based inorganic film, but the disclosure is not limited thereto.

The eleventh insulating film INS11 may be disposed on the tenth insulating film INS10 and the reflective electrode layer RL. The eleventh insulating film INS11 may be formed of a silicon oxide (SiOₓ)-based inorganic film, but the disclosure is not limited thereto. The tenth insulating film INS10 and the eleventh insulating film INS11 may function as an optical auxiliary layer through which light reflected by the reflective electrode layer RL passes, among the light emitted from the light-emitting elements LE.

In order to match the resonance distance of the light emitted from the light-emitting elements LE in at least one of the first sub-pixel SP1, the second sub-pixel SP2, or the third sub-pixel SP3, the eleventh insulating film INS11 may not be disposed under the first electrode AND. For example, the first electrode AND of the first sub-pixel SP1 may be directly disposed on the reflective electrode layer RL. The eleventh insulating film INS11 may be disposed under the first electrode AND of the second sub-pixel SP2. The tenth insulating film INS10 and the eleventh insulating film INS11 may be disposed under the first electrode AND of the third sub-pixel SP3.

In summary, the distance between the first electrode AND and the reflective electrode layer RL may vary in the first sub-pixel SP1, the second sub-pixel SP2, and the third sub-pixel SP3. In order to adjust the distance from the reflective electrode layer RL to the first electrode AND based on the main wavelength of the light emitted from each of the first sub-pixel SP1, the second sub-pixel SP2, and the third sub-pixel SP3, a thickness of the eleventh insulating film INS11 may differ in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2, and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The disclosure is not limited to the above examples.

Each of the tenth vias VA10 may penetrate the eleventh insulating film INS11 in the second sub-pixel SP2 and the third sub-pixel SP3 and may be connected to the exposed fourth reflective electrode RL4. The tenth vias VA10 may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. The thickness of the tenth via VA10 in the second sub-pixel SP2 may be less than the thickness of the tenth via VA10 in the third sub-pixel SP3.

The first electrode AND of each of the light-emitting elements LE may be disposed on the eleventh insulating film INS11 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of at least one of copper (Cu), aluminum (Al), tungsten (W), molybdenum (Mo), chromium (Cr), gold (Au), titanium (Ti), nickel (Ni), neodymium (Nd), or an alloy including two or more of them. For example, the first electrode AND of each of the light-emitting elements LE may be titanium nitride (TiN).

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed at the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the disclosure is not limited thereto. The first pixel defining film PDL1, the second pixel defining film PDL2, and the third pixel defining film PDL3 may each have a thickness of about 500 Å.

In the case where the first pixel defining film PDL1, the second pixel defining film PDL2, and the third pixel defining film PDL3 are formed as a single pixel defining film, the height of the single pixel defining film may increase, so that a first encapsulation inorganic film TFE1 may be cut off due to step coverage. Step coverage may refer to the ratio of the degree of thin film coated on an inclined portion to the degree of thin film coated on a flat portion. The lower the step coverage, the more likely it is that the thin film will be cut off at inclined portions.

Therefore, in order to reduce or prevent the first encapsulation inorganic film TFE1 from being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 may refer to the horizontal length of the first pixel defining film PDL1 defined in the first direction DR1 and the second direction DR2.

The light-emitting stack IL may include multiple intermediate layers. The light-emitting stack IL may include a first stack layer IL1, a second stack layer IL2, and a third stack layer IL3, each emitting different lights. The first stack layer IL1, the second stack layer IL2, and the third stack layer IL3 may be discontinuous between adjacent sub-pixels.

The first stack layer IL1 may have a structure in which a first hole transport layer, a first organic light-emitting layer that emits first light, and a first electron transport layer are sequentially stacked. The first stack layer IL1 may be disposed on the first electrodes AND and the pixel defining film PDL in the first emission area EA1 of the first sub-pixel SP1.

The second stack layer IL2 may have a structure in which a second hole transport layer, a second organic light-emitting layer that emits third light, and a second electron transport layer are sequentially stacked. The second stack layer IL2 may be disposed on the first electrodes AND and the pixel defining film PDL in the second emission area EA2 of the second sub-pixel SP2.

The third stack layer IL3 may have a structure in which a third hole transport layer, a third organic light-emitting layer that emits second light, and a third electron transport layer are sequentially stacked. The third stack layer IL3 may be disposed on the first electrodes AND and the pixel defining film PDL in the third emission area EA3 of the third sub-pixel SP3.

The second electrode CAT may be disposed on the third stack layer IL3 and the pixel defining film PDL. The second electrode CAT may be formed of a transparent conductive material (TCO), such as ITO or IZO, that can transmit light or a semi-transmissive conductive material, such as magnesium (Mg), silver (Ag), or an alloy of Mg and Ag. In the case where the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film, such as TFE1 and TFE2, to reduce or prevent oxygen or moisture from permeating into the display element layer EML. For example, the encapsulation layer TFE may include a first encapsulation inorganic film TFE1 and a second encapsulation inorganic film TFE2.

The first encapsulation inorganic film TFE1 may be disposed on the second electrode CAT. The first encapsulation inorganic film TFE1 may be formed as a multilayer in which one or more inorganic films, selected from silicon nitride (SiNₓ), silicon oxy nitride (SiOₓN_{y}), and silicon oxide (SiOₓ), are alternately stacked. The first encapsulation inorganic film TFE1 may be formed using a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but the disclosure is not limited thereto. The second encapsulation inorganic film TFE2 may be formed using an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the cover layer CVL. The organic film APL may be formed of materials such as acrylic resin, epoxy resin, phenolic resin, polyamide resin, or polyimide resin.

The cover layer CVL may be disposed on the organic film APL. The cover layer CVL may be formed of glass or polymer resin.

The polarizing plate POL may be disposed on a surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a N4 plate (quarter-wave plate), but the disclosure is not limited thereto.

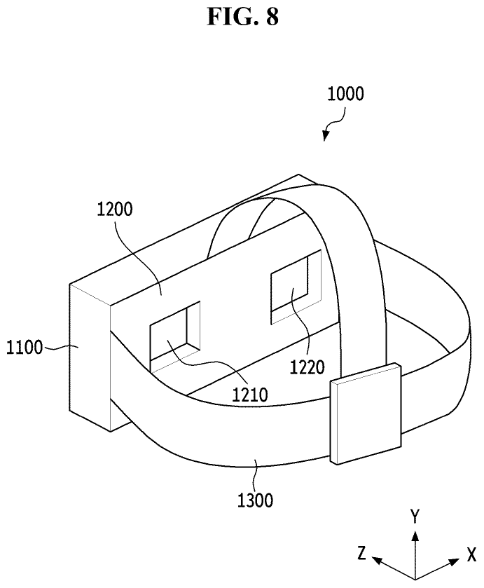

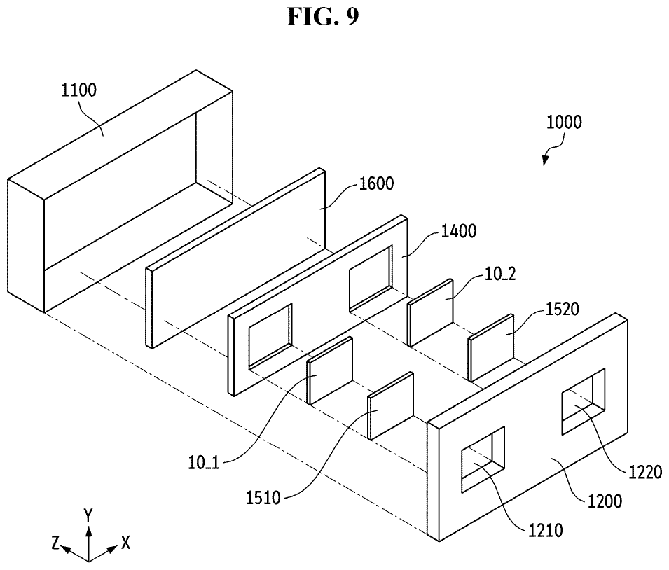

FIG. 8 is a schematic perspective view illustrating a head mounted display according to an embodiment. FIG. 9 is an exploded schematic perspective view illustrating an example of the head mounted display of FIG. 8.

Referring to FIGS. 8 and 9, a head mounted display 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 may provide an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 may serve to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source received from the outside into the digital video data DATA and transmit the digital video data DATA to the first display device 10_1 and the second display device 10_2 through the connector.

The control circuit board 1600 may transmit the digital video data DATA corresponding to a left-eye image, optimized for the user's left eye, to the first display device 10_1, and may transmit the digital video data DATA corresponding to a right-eye image, optimized for the user's right eye, to the second display device 10_2. In another embodiment, the control circuit board 1600 may transmit the same digital video data DATA to both the first display device 10_1 and the second display device 10_2.

The display device housing 1100 may serve to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210, located for the user's left eye, and the second eyepiece 1220, located for the user's right eye. FIGS. 8 and 9 illustrate that the first eyepiece 1210 and the second eyepiece 1220 are disposed separately, but the disclosure is not limited thereto. The first eyepiece 1210 and the second eyepiece 1220 may also be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image from the first display device 10_1, magnified as a virtual image by the first optical member 1510, and may view, through the second eyepiece 1220, the image from the second display device 10_2, magnified as a virtual image by the second optical member 1520.

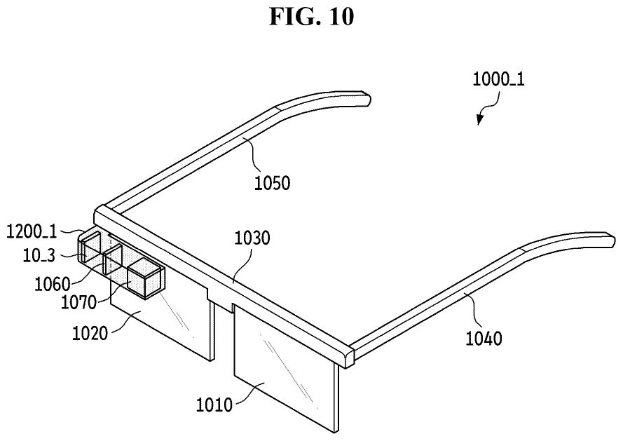

The head mounted band 1300 may function to secure the display device housing 1100 to the user's head, such that the first eyepiece 1210 and the second eyepiece 1220 of the housing cover 1200 remain located over the user's left and right eyes, respectively. In the case where the display device housing 1200 is implemented to be lightweight and compact, the head mounted display 1000 may, as shown in FIG. 10, be provided with an eyeglass frame instead of the head mounted band 1300.

The head mounted display 1000 may further include a battery for supplying power, an external memory slot for accommodating an external memory, and an external connection port as well as a wireless communication module for receiving an image source. The external connection port may include a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating a head mounted display according to an embodiment.

Referring to FIG. 10, a head mounted display 1000_1 according to an embodiment may be an eyeglasses-type display device, in which a display device housing 1200_1 is implemented in a lightweight and compact form. The head mounted display 1000_1 may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060 and provided to the user's right eye through the right eye lens 1020 after the optical path thereof is changed by the optical path changing member 1070. As a result, the user may view an augmented reality image through the right eye, in which a virtual image displayed on the display device 10_3 is combined with a real image seen through the right eye lens 1020.

FIG. 10 illustrates that the display device housing 1200_1 is disposed at the right end of the support frame 1030, but the disclosure is not limited thereto. For example, the display device housing 1200_1 may be disposed at the left end of the support frame 1030, and the image of the display device 10_3 may be provided to the user's left eye. In another embodiment, the display device housing 1200_1 may be disposed at both the left and right ends of the support frame 1030, and the user may view the image displayed on the display device 10_3 through both the left and right eyes.

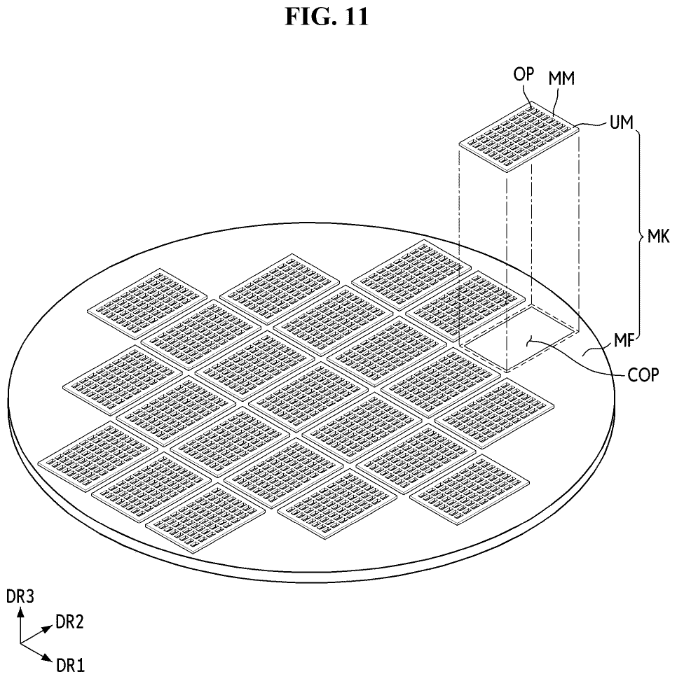

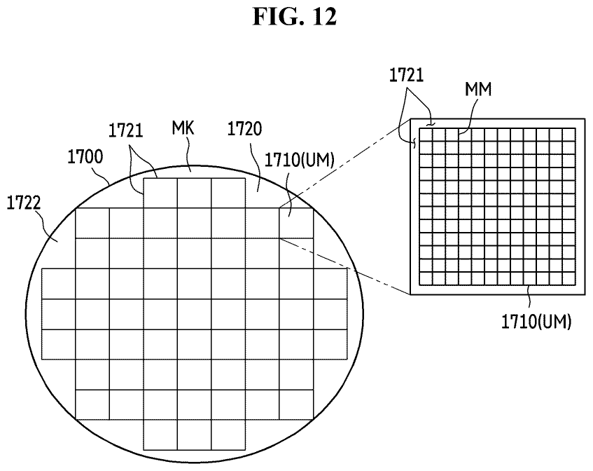

FIG. 11 is a schematic perspective view of a mask according to an embodiment. FIG. 12 is a schematic plan view of a mask according to an embodiment. FIG. 11 shows a schematic perspective view of a unit mask UM separated from multiple unit masks. The mask shown in FIGS. 11 and 12 may be used in the process of depositing at least a portion of the light-emitting stack IL described with reference to FIG. 7. For example, the light-emitting stack IL may emit different colors in each of the sub-pixels SP1, SP2, and SP3.

Referring to FIGS. 11 and 12, a mask MK according to an embodiment may be a shadow mask, in which a mask membrane MM is disposed on a silicon substrate 1700. The mask MK may also be referred to as a “silicon mask.”

According to an embodiment, the mask MK may include the silicon substrate 1700 (or “substrate”), and the mask membrane MM may be disposed on the silicon substrate 1700. The mask membrane MM may be disposed in cell regions 1710 arranged in a matrix form, and each cell region 1710 may be surrounded by a mask rip region 1721. The mask rip region 1721 may have a portion of the silicon substrate 1700 disposed therein, and may serve to support the mask membrane MM.

The mask membrane MM may form part of the unit mask UM disposed in each of the cell regions 1710.

The silicon substrate 1700 may include the cell regions 1710 and a mask frame region 1720 that excludes the cell regions 1710. The mask frame region 1720 may include the mask rip region 1721 surrounding each cell region 1710 and an outer frame region 1722 disposed at the outermost edge of the silicon substrate 1700. A mask frame MF may be disposed in the mask frame region 1720, and the mask frame MF may include a mask rip surrounding the cell region 1710.

The mask rip region 1721 may partition the multiple cell regions 1710. For example, the cell regions 1710 may be arranged in a matrix form, and the mask rip disposed in the mask rip region 1721 may surround the outer edge of the mask membrane MM disposed in each cell region 1710.

A cell opening COP and the unit mask UM for masking at least a portion of the cell opening COP may be disposed in each of the cell regions 1710 of the silicon substrate 1700.

The multiple cell openings COP may penetrate the mask frame MF along a thickness direction (e.g., the third direction DR3) of the mask MK. These cell openings COP may be formed by etching a portion of the silicon substrate 1700 from the rear side.

Each unit mask UM may include the mask membrane MM, and the mask membrane MM may include a mask opening.

The mask opening of the mask membrane MM may be referred to as a “hole” or “mask hole.” The mask openings may penetrate the unit masks UM along the thickness direction (e.g., the third direction DR3) of the mask MK.

One unit mask UM may be used in the deposition process of a display panel 100. In the disclosure, the term “unit mask UM” may also be referred to as a “mask unit” UM.

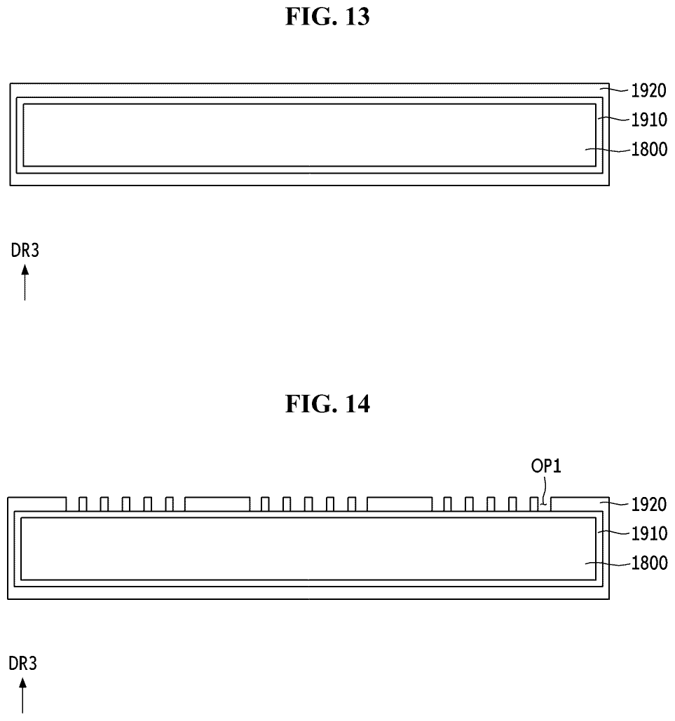

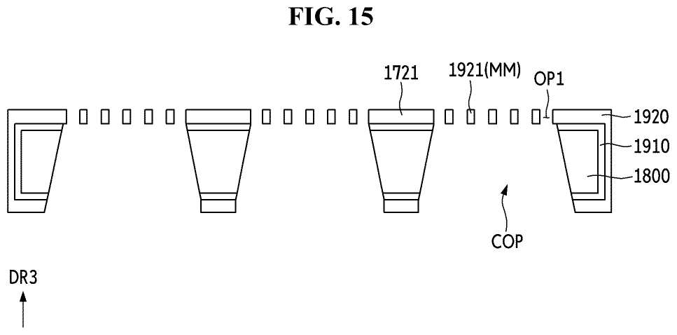

FIGS. 13 to 15 are schematic process cross-sectional views illustrating a method of manufacturing a mask according to an embodiment. For example, FIG. 15 may be a schematic cross-sectional view in which a portion of the mask is cut, and FIGS. 13 to 15 may sequentially illustrate a process of manufacturing the mask.

Hereinafter, a method of manufacturing a mask according to an embodiment will be described with reference to FIGS. 13 to 15.

Referring to FIG. 13, a substrate 1800 (e.g., 1700 in FIG. 12) may be provided. The substrate 1800 may contain silicon (Si). The substrate 1800 may also be referred to as “body substrate” or “membrane substrate,” but is not limited thereto.

When the substrate 1800 is provided, an inorganic film 1910 and 1920 may be deposited on the substrate 1800. The inorganic film 1910 and 1920 may be deposited across the entire surface of the substrate 1800. For example, the inorganic film 1910 and 1920 may be deposited on the front surface, the side surface, and the rear surface of the substrate 1800.

According to an embodiment, the inorganic film 1910 and 1920 may include a single film. For example, the inorganic film 1910 and 1920 may include a first inorganic film 1910, and the first inorganic film 1910 may contain at least one material selected from silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

According to an embodiment, the inorganic film 1910 and 1920 may include multiple films. For example, the inorganic film may include a first inorganic film 1910 and a second inorganic film 1920 disposed on the first inorganic film 1910. The first inorganic film 1910 may contain silicon oxide (SiOₓ), and the second inorganic film 1920 may contain silicon nitride (SiNₓ). However, the material of each of the first inorganic film 1910 and the second inorganic film 1920 is not limited thereto. For example, each of the first inorganic film 1910 and the second inorganic film 1920 may contain at least one material selected from silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

Hereinafter, an embodiment in which the first inorganic film 1910 and the second inorganic film 1920 are deposited on the substrate 1800 will be described.

Referring to FIG. 14, the second inorganic film 1920 is patterned to form a second inorganic film pattern 1921 (see FIG. 15) including multiple openings OP1. For example, as described with reference to FIG. 12, the multiple cell regions 1710 (see FIG. 12) are defined in the substrate 1800. A portion of the second inorganic film 1920 corresponding to the multiple cell regions 1710 of the substrate 1800 is patterned, resulting in the formation of multiple second inorganic film patterns 1921. The second inorganic film pattern 1921 may become part of the mask membrane MM after the mask manufacturing process is completed.

The process of patterning the second inorganic film 1920 may include the following steps as part of a dry etching process for the second inorganic film 1920. A photoresist pattern may be formed on the second inorganic film 1920. Subsequently, a portion of the second inorganic film 1920 located in the cell region 1710 may be etched using the photoresist pattern as a mask. Accordingly, the second inorganic film 1920 overlapping the photoresist pattern may remain and become the second inorganic film pattern 1921, while the etched portion, using the photoresist pattern as a mask, may become the opening OP1 of the mask membrane MM.

Referring to FIG. 15, the second inorganic film 1920, the substrate 1800, and the first inorganic film 1910 are etched from the lower side of the substrate 1800 to form the cell opening COP, exposing the second inorganic film pattern 1921. The process of forming the cell opening COP may include a wet etching process of patterning the substrate 1800, which contains silicon (Si), and the first inorganic film 1910, which contains silicon oxide (SiOₓ).

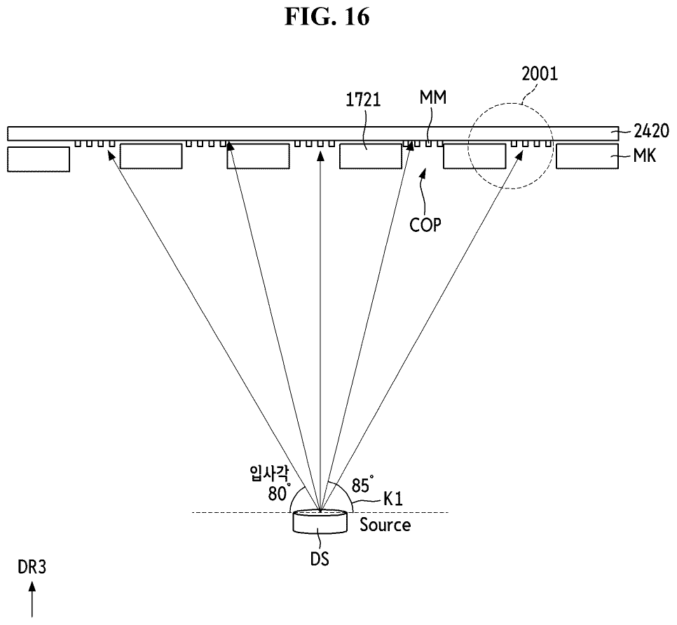

FIG. 16 is a schematic conceptual diagram explaining a shadow defect that occurs during a deposition process using a mask.

Referring to FIG. 16, during a deposition process using a mask MK, a deposition source DS may be prepared to face one surface of the mask MK (e.g., the lower surface of the mask MK), while a deposition substrate 2420 (e.g., first substrate or a display panel 100 shown in FIGS. 1 to 10) is aligned to face the other surface of the mask MK (e.g., the upper surface of the mask MK).

When the deposition substrate 2420 and the mask MK are aligned, a deposition material contained in the deposition source DS is vaporized, and the vaporized deposition material passes through the cell opening COP of the mask MK and is deposited onto the deposition substrate 2420. At this time, deposition incidence angle K1 from the deposition source DS to each of the cell openings COP of the mask MK may vary. For example, the deposition incidence angle K1 may be greater toward the center portion of the mask MK and may be smaller toward the outer edge of the mask MK.

The cell opening COP located on the outer edge of the mask MK may have a relatively small deposition incidence angle K1, which increases a shadow area due to the mask rip region 1721. For example, in cell areas located near the outer edge of the mask MK, such as area 2001 in FIG. 16, shadow defects or color mixing defects may increase.

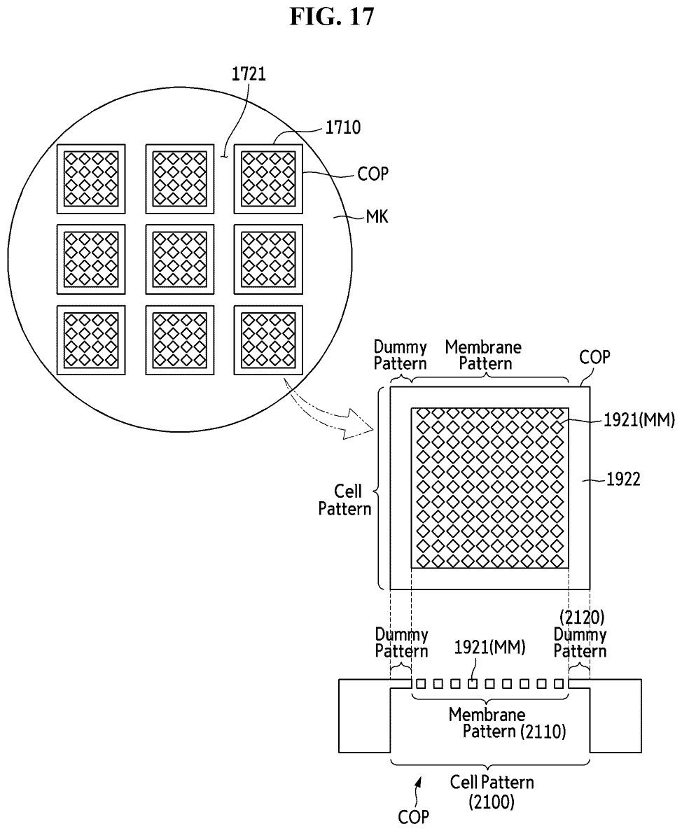

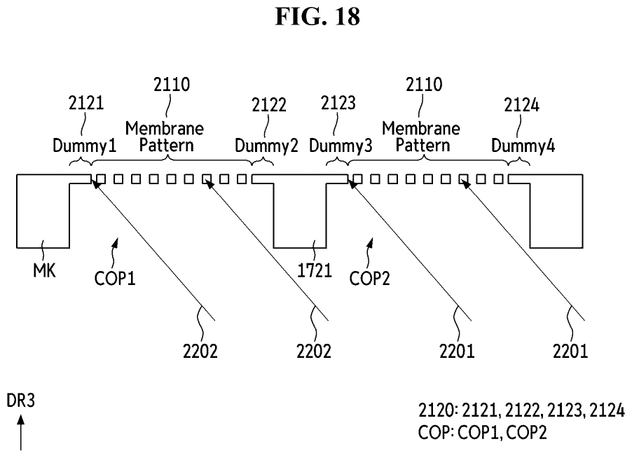

FIGS. 17 to 18 are schematic configuration diagrams of a mask according to a comparative example. For example, FIG. 17 illustrates a schematic plan view and a schematic cross-sectional view of a cell pattern disposed in a cell opening of a mask according to a comparative example. FIG. 18 is a schematic cross-sectional view of a mask illustrating a cell pattern disposed in a cell opening illustrated in FIG. 17.

Referring to FIGS. 17 and 18, a mask according to a comparative example includes a cell pattern 2100 disposed in each of the cell openings and formed by an inorganic film. The inorganic film forming the cell pattern 2100 may correspond to the inorganic films 1910 and 1920 described with reference to FIGS. 13 to 15.

The cell pattern 2100 includes a mask membrane pattern 2110 including a multiple openings OP1 (see FIG. 15) and a dummy pattern 2120 surrounding the mask membrane pattern 2110. The mask membrane pattern 2110 may include a mask membrane MM described with reference to FIGS. 13 to 15. The dummy pattern 2120 is disposed on the outer edge of the mask membrane pattern 2110. For example, the dummy pattern 2120 is disposed at the boundary of the cell opening COP and adjacent to the mask rip region 1721 of the mask MK. The dummy pattern 2120 may function to relieve stress or tension applied to the mask membrane pattern 2110.

In the mask MK according to the comparative example, when viewed in a plan view, the width of the dummy pattern 2120 surrounding the mask membrane pattern 2110 is uniform. For example, when in a plan view, the dummy pattern 2120 is disposed along each of a first side direction (e.g., left direction) of the mask membrane pattern 2110, a second side direction (e.g., right direction) opposite to the first side direction, a third side direction (e.g., upper direction) perpendicular to the first side direction, and a fourth side direction (e.g., lower direction) opposite to the third side direction, and the widths thereof are uniform.

According to the comparative example, the mask MK includes multiple cell openings COP, and the widths of the dummy patterns 2120 disposed in each of the cell openings COP are all the same. For example, as illustrated in FIG. 18, the mask MK includes a first cell opening COP1 and a second cell opening COP2 adjacent to the first cell opening COP1. The first cell opening COP1 is spaced apart by a first distance from the center portion of the mask MK (e.g., the center portion of the substrate 1800 in FIG. 15). The second cell opening COP2 is spaced apart by a second distance, smaller than the first distance, from the center portion of the mask MK (e.g., the center portion of the substrate 1800 in FIG. 15).

According to the comparative example, the dummy pattern 2120 surrounding the outer edge of the mask membrane pattern 2110 is disposed in the first cell opening COP1, and the dummy pattern 2120 includes a first dummy pattern 2121 disposed on one side (e.g., left side) of the mask membrane pattern 2110 and a second dummy pattern 2122 disposed on the opposite side (e.g., right side) of the mask membrane pattern 2110.

According to the comparative example, the width of the first dummy pattern 2121 and the width of the second dummy pattern 2122 in the first cell opening COP1 are the same.

Similarly, in the second cell opening COP2, the dummy pattern 2120 is disposed surrounding the outer edge of the mask membrane pattern 2110, and the dummy pattern 2120 includes a third dummy pattern 2123 disposed on one side of the mask membrane pattern 2110 and a fourth dummy pattern 2124 disposed on the opposite side of the mask membrane pattern 2110.

In the comparative example, the width of the third dummy pattern 2123 and the width of the fourth dummy pattern 2124 in the second cell opening COP2 are also the same.

According to the comparative example, a deposition incidence angle 2202 from the deposition source DS (see FIG. 16) to the first cell opening COP1 is smaller than a deposition incidence angle 2201 from the deposition source DS to the second cell opening COP2. The deposition incidence angle 2202 with respect to the first cell opening COP1 and the deposition incidence angle 2201 with respect to the second cell opening COP2 are different from each other. Accordingly, the shadow area generated in the first cell opening COP1 is greater than the shadow area generated in the second cell opening COP2. According to the comparative example, although the deposition incidence angles 2201 and 2202 in respect to the first cell opening COP1 and the second cell opening COP2 are different from each other, the width of each of the dummy patterns 2121 and 2122 disposed in the first cell opening COP1 and the width of each of the dummy patterns 2123 and 2124 disposed in the second cell opening COP2 are the same. In such comparative example, due to the uniform width of the dummy pattern 2120, shadow defects or color mixing defects may increase toward the outer edge of the mask MK.

Hereinafter, a mask according to an embodiment for reducing shadow defects or color mixing defects of a mask, compared to the mask of the comparative example, will be described.

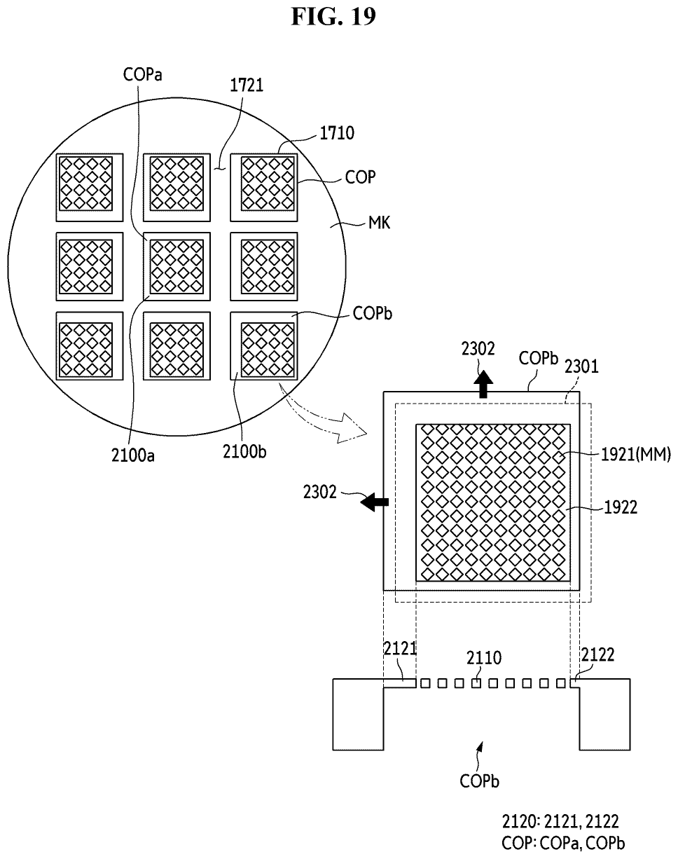

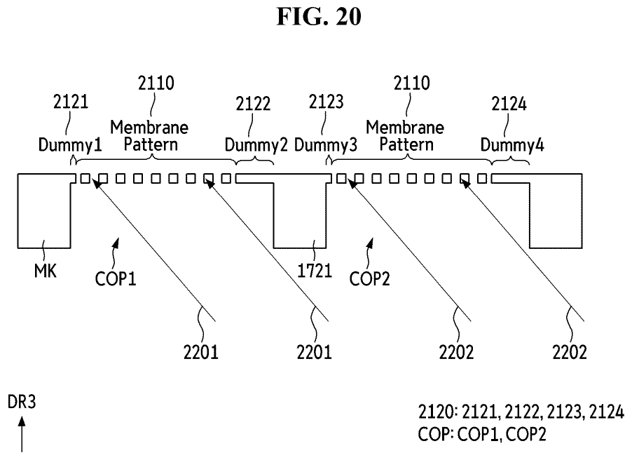

FIGS. 19 to 20 are schematic configuration diagrams of a mask according to an embodiment. For example, FIG. 19 illustrates a schematic plan view and a schematic cross-sectional view of a cell pattern 2100 disposed in a cell opening of a mask according to an embodiment. FIG. 20 is a schematic cross-sectional view illustrating a cell pattern 2100 disposed in a cell opening illustrated in FIG. 19.

The mask MK according to an embodiment may include a cell pattern 2100 disposed in each of the multiple cell openings COP and formed by an inorganic film. The inorganic film forming the cell pattern 2100 may correspond to the inorganic film 1910 and 1920 described with reference to FIGS. 13 to 15. For example, the inorganic film may contain at least one material selected from silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

The cell pattern 2100 may include a mask membrane pattern 2110 including multiple openings OP1 (see FIG. 15) and a dummy pattern 2120 surrounding the mask membrane pattern 2110. The mask membrane pattern 2110 may include a mask membrane MM described with reference to FIGS. 13 to 15. The dummy pattern 2120 may be disposed on the outer edge of the mask membrane pattern 2110. For example, the dummy pattern 2120 may be disposed at the boundary of the cell opening COP and adjacent to the mask rip region 1721 of the mask MK. Such dummy pattern 2120 may serve to relieve stress or tension applied to the mask membrane pattern 2110.

In the mask MK according to an embodiment, in a plan view, the width of the dummy pattern 2120 surrounding the mask membrane pattern 2110 may be not uniform (or irregular). For example, when in a plan view, the dummy pattern 2120 may be disposed in each of a first side direction (e.g., left direction) of the mask membrane pattern 2110, a second side direction (e.g., right direction) opposite to the first side direction, a third side direction (e.g., upper direction) perpendicular to the first side direction, and a fourth side direction (e.g., lower direction) opposite to the third side direction, and the widths thereof are not uniform (or irregular).

According to an embodiment, the multiple cell openings COP may include at least one first type cell opening COPa adjacent to the center portion of the substrate 1800 (see FIG. 15) including a first cell pattern 2100a, and multiple second type cell openings COPb disposed at the periphery of the first type cell opening COPa, including a second cell pattern 2100b. The width of the dummy pattern 2120 included in the first cell pattern 2100a is uniform, while the width of the dummy pattern 2120 included in the second cell pattern 2100b is not uniform (or irregular). For example, reference numeral 2301 illustrates the alignment of the dummy pattern 2120 in a comparative example in FIG. 19, and such dummy pattern 2120 may be designed to shift toward the center portion of the substrate 1800 (i.e., the center portion of the mask), as indicated by arrow 2302.

The first type cell opening COPa may include the first cell pattern 2100a having a uniform width because the first type cell opening COPa is located near the center portion of the substrate 1800. Since the first type cell opening COPa is close to the center portion of the substrate 1800, the deposition incidence angle is approximately 90 degrees, and thus, no shadow defects occur. Accordingly, even when the first type cell opening COPa includes the dummy pattern 2120 having a uniform width, the likelihood of shadow defects is low. According to an embodiment, the first cell pattern 2100a of the first type cell opening COPa may include a first dummy pattern 2121 disposed on one side of the mask membrane pattern 2110 having a first width, and a second dummy pattern 2122 disposed on the opposite side of the mask membrane pattern 2110 having the first width.

On the other hand, the second type cell opening COPb may include the dummy patterns 2121 and 2122 having non-uniform (or irregular) widths because the second type cell opening COPb is farther from the center portion of the substrate 1800, and the deposition incidence angle is smaller than 90 degrees. Accordingly, since the second type cell opening COPb has a higher likelihood of shadow defects, the width of each of the dummy patterns 2121 and 2122 is adjusted to be not uniform (or irregular). According to an embodiment, the second type cell opening COPb may include a first dummy pattern 2121 disposed on one side of the mask membrane pattern 2110 having a first width, and a second dummy pattern 2122 disposed on the other side of the mask membrane pattern 2110 having a second width smaller than the first width. The second dummy pattern 2122 may be disposed closer to the center portion of the substrate than the first dummy pattern 2121.

Referring to FIG. 20, the multiple second cell openings COPb may include a first cell opening COP1 and a second cell opening COP2.

The first cell opening COP1 may include a first dummy pattern 2121 and a second dummy pattern 2122, which are spaced apart by a first distance from the center portion of the substrate 1800 (see FIG. 15).

The second cell opening COP2 may include a third dummy pattern 2123 and a fourth dummy pattern 2124, which are spaced apart by a second distance smaller than the first distance from the center portion of the substrate 1800 (see FIG. 15).

According to an embodiment, each of the first to fourth dummy patterns 2121, 2122, 2123, and 2124 has a different width. For example, the first dummy pattern 2121 has a first width, the second dummy pattern 2122 has a second width greater than the first width, the third dummy pattern 2123 has a third width, and the fourth dummy pattern 2124 has a fourth width greater than the third width. The first width and the third width are different, and the second width and the fourth width are also different from each other.

The widths of each of the dummy patterns provided in the first cell opening COP1 (i.e., the first dummy pattern 2121 and the second dummy pattern 2122) and dummy patterns provided in the second cell opening COP2 (i.e., the third dummy pattern 2123 and the fourth dummy pattern 2124) are different, due to the design considerations accounting for the different deposition incidence angles 2201 for the first cell opening COP1 and 2202 for the second cell opening COP2. In the mask MK according to an embodiment, by allowing the widths of the dummy patterns provided in the first cell opening COP1 and the dummy patterns provided in the second cell opening COP2 to be different, shadow defects may be reduced.

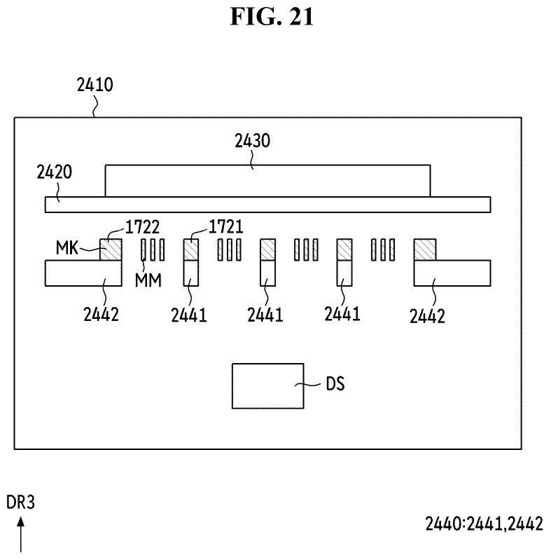

FIG. 21 is a schematic configuration diagram illustrating deposition equipment (or a deposition apparatus) according to an embodiment.

Referring to FIG. 21, the deposition equipment (or deposition apparatus) according to an embodiment may include a chamber 2410, the deposition source DS disposed inside the chamber 2410, the mask MK disposed between a first substrate 2420 and the deposition source DS inside the chamber 2410, and a mask support 2440 disposed between the deposition source DS and the mask MK to support at least a portion of the mask MK.

According to an embodiment, the mask MK may include a second substrate 1700 (see FIG. 12) including the multiple cell regions 1710 (see FIG. 12) and the mask frame region 1720 (see FIG. 12) excluding the cell regions 1710, and the mask membrane MM disposed in each cell region 1710.

The first substrate 2420 shown in FIG. 21 may correspond to the display panel 100 described with reference to FIGS. 1 to 10. Therefore, the description of the first substrate 2420 is replaced with the description of the display panel 100 with reference to FIGS. 1 to 10.

The mask MK shown in FIG. 21 may represent a second substrate and may include the silicon substrate 1700 or the substrate 1800 described with reference to FIGS. 13 to 20. The description of the second substrate is replaced with the description of the silicon substrate 1700 or the substrate 1800 with reference to FIGS. 13 to 20.

The mask support 2440 may serve to support and fix the mask MK. For example, the mask support 2440 may include an electrostatic chuck. According to an embodiment, the mask support 2440 may include a first support region 2441 that supports the mask rip region 1721 and a second support region 2442 that supports the outer frame region 1722. In another embodiment, the mask support 2440 may omit the first support region 2441 and may not support the mask rip region 1721.

The reference numeral 2430 shown in FIG. 21 may represent a fixing member 2430 that secures the first substrate 2420. The fixing member 2430 may include, for example, an electrostatic chuck.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A deposition mask comprising:
a substrate; and
a cell pattern disposed in each of a plurality of cell openings of the substrate, formed by an inorganic film, wherein
the cell pattern comprises:
a mask membrane pattern comprising a plurality of openings; and
a dummy pattern surrounding the mask membrane pattern, where a width of the dummy pattern is irregular.

2. The deposition mask of claim 1, wherein
the plurality of cell openings comprises:
at least one first type cell opening adjacent to a center portion of the substrate, comprising a first cell pattern; and
a plurality of second type cell openings disposed at a periphery of the first type cell opening, comprising a second cell pattern, and
the width of a dummy pattern included in the first cell pattern is uniform, and the width of a dummy pattern included in the second cell pattern is irregular.

3. The deposition mask of claim 2, wherein
the first cell pattern comprises:
a first dummy pattern disposed on a side of the mask membrane pattern and having a first width; and
a second dummy pattern disposed on another side of the mask membrane pattern and having the first width.

4. The deposition mask of claim 2, wherein
the second cell pattern comprises:
a first dummy pattern disposed on a side of the mask membrane pattern and having a first width; and
a second dummy pattern disposed on another side of the mask membrane pattern and having a second width greater than the first width, and
the second dummy pattern is closer to the center portion of the substrate than the first dummy pattern.

5. The deposition mask of claim 2, wherein
the plurality of second type cell openings comprises:
a first cell opening comprising a first dummy pattern and a second dummy pattern, spaced apart from the center portion of the substrate by a first distance; and
a second cell opening comprising a third dummy pattern and a fourth dummy pattern, spaced apart from the center portion of the substrate by a second distance smaller than the first distance, and
the width of each of the first, second, third, and fourth dummy patterns is different from one another.

6. The deposition mask of claim 5, wherein
the first dummy pattern has a first width,
the second dummy pattern has a second width greater than the first width,
the third dummy pattern has a third width, and
the fourth dummy pattern has a fourth width greater than the third width.

7. The deposition mask of claim 6, wherein the first width is different from the third width, and the second width is different from the fourth width.

8. The deposition mask of claim 1, wherein
the inorganic film comprises:
a first inorganic film containing silicon oxide (SiOₓ); and
a second inorganic film disposed on the first inorganic film, containing silicon nitride (SiNₓ).

9. The deposition mask of claim 1, wherein the inorganic film includes at least one of silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

10. The deposition mask of claim 1, wherein the substrate includes silicon (Si).

11. A deposition apparatus comprising:
a deposition source; and
a mask disposed between a first substrate and the deposition source, comprising a second substrate and a cell pattern disposed in each of a plurality of cell openings of the second substrate formed by an inorganic film, wherein
the cell pattern comprises:
a mask membrane pattern comprising a plurality of openings; and
a dummy pattern surrounding the mask membrane pattern, where a width of the dummy pattern is irregular.

12. The deposition apparatus of claim 11, wherein
the plurality of cell openings comprises:
at least one first type cell opening adjacent to a center portion of the second substrate, comprising a first cell pattern; and
a plurality of second type cell openings disposed at a periphery of the first type cell opening, comprising a second cell pattern, and
the width of a dummy pattern included in the first cell pattern is uniform, and the width of a dummy pattern included in the second cell pattern is irregular.

13. The deposition apparatus of claim 12, wherein
the first cell pattern comprises:
a first dummy pattern disposed on a side of the mask membrane pattern and having a first width; and
a second dummy pattern disposed on another side of the mask membrane pattern and having the first width.

14. The deposition apparatus of claim 12, wherein
the second cell pattern comprises:
a first dummy pattern disposed on a side of the mask membrane pattern and having a first width; and
a second dummy pattern disposed on another side of the mask membrane pattern and having a second width greater than the first width, and
the second dummy pattern is closer to the center portion of the second substrate than the first dummy pattern.

15. The deposition apparatus of claim 12, wherein
the plurality of second type cell openings comprises:
a first cell opening comprising a first dummy pattern and a second dummy pattern, spaced apart from the center portion of the second substrate by a first distance; and
a second cell opening comprising a third dummy pattern and a fourth dummy pattern, spaced apart from the center portion of the second substrate by a second distance smaller than the first distance, and
the width of each of the first, second, third, and fourth dummy patterns is different from one another.

16. The deposition apparatus of claim 15, wherein
the first dummy pattern has a first width,
the second dummy pattern has a second width greater than the first width,
the third dummy pattern has a third width, and
the fourth dummy pattern has a fourth width greater than the third width.

17. The deposition apparatus of claim 16, wherein
the first width is different from the third width, and
the second width is different from the fourth width.

18. The deposition apparatus of claim 11, wherein
the inorganic film comprises:
a first inorganic film containing silicon oxide (SiOₓ); and
a second inorganic film disposed on the first inorganic film, containing silicon nitride (SiNₓ).

19. The deposition apparatus of claim 11, wherein the inorganic film contains at least one of silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

20. The deposition apparatus of claim 11, wherein the second substrate contains silicon (Si).
